(19) United States
(12) Patent Application Publication
(10) Pub. No.: US 2016/0199887 A1
(43) Pub. Date: Jul. 14, 2016

(54) DESMEARING METHOD AND DESMEARING APPARATUS

(71) Applicant: USHIO DENKI KABUSHIKI KAISHA, Tokyo (JP)

(72) Inventors: Noritaka TAKEZOE, Himeji-shi (JP); Tetsuya MURAKAMI, Himeji-shi (JP); Shintaro YABU, Tokyo (JP)

(73) Assignee: USHIO DENKI KABUSHIKI KAISHA, Tokyo (JP)

(21) Appl. No.: 14/912,447

(22) PCT Filed: Aug. 12, 2014
(86) PCT No.: PCT/JP2014/071296

§ 371 Date: Feb. 17, 2016

(30) Foreign Application Priority Data
Aug. 23, 2013 (JP) 2013-173084

(51) Int. Cl. B08B 7/00; B08B 3/12; H05K 3/00

(52) U.S. Cl. CPC B08B 7/0057; H05K 3/0055; B08B 3/123; H05K 2203/0292

(57) ABSTRACT

Provided are a desmearing method which can reliably remove a smear caused either by an inorganic substance or by an organic substance, and a desmearing apparatus which carries out this desmearing method. The desmearing method is used for a wiring substrate material which is obtained by laminating a conductive layer and an insulating layer. The insulating layer is formed of a resin containing a filler. The desmearing method includes a wet-type ultraviolet beam irradiation step of irradiating a portion to be processed in the wiring substrate material with an ultraviolet beam in a gas atmosphere while maintaining the portion to be processed in a wet state. Ozone and oxygen are present in the gas atmosphere. The desmearing method also includes a physical vibration applying step of applying physical vibrations to the wiring substrate material after the wet-type ultraviolet beam irradiation step.

### TECHNICAL FIELD

The present invention relates to a method of desmearing a wiring substrate material, which has a lamination of an insulation layer and a conductive layer, and an apparatus for carrying out the desmearing method. The insulation layer is made from resin that contains a filler.

### BACKGROUND ART

A multi-layer wiring substrate is known as an example of wiring substrate that supports semiconductor elements, such as semiconductor integrated circuitry elements, thereon. The multi-layer wiring substrate has insulation layers and conductive layers (wiring layers) that are alternately stacked one after another. In such multi-layer wiring substrate, via holes and/or through holes are formed in order to electrically connect one conductive layer with another conductive layer. The via holes and the through holes extend through one or more insulation layers in the thickness direction of the wiring substrate.

When the multi-layer wiring substrate is fabricated, drilling or laser beam machining is applied to the wiring substrate material, which is a lamination of insulation layers and conductive layers, to remove certain portions from the insulation layers and/or the conductive layers thereby forming via holes and/or through holes. When the via holes and/or through holes are formed, smears (residues) that are derived from the materials of the insulation layers and the conductive layers is created (left) on the wiring substrate material. Thus, a desmearing process is carried out to the wiring substrate material in order to remove (clear away) the smears.

One of the known or conventional desmearing methods to be applied to the wiring substrate material is a wet-type desmearing method, and another known method is a dry-type desmearing method (see Patent Literature Document 1 and Patent Literature Document 2).

In the wet-type desmearing method, an alkaline solution is prepared by dissolving potassium permanganate or sodium hydroxide in a solvent, and the wiring substrate material is immersed in the alkaline solution such that the smears remaining on the wiring substrate material are dissolved or peeled off, thereby removing the smears. In the dry-type desmearing method, the wiring substrate material is irradiated with an ultraviolet beam such that an ozone is generated upon irradiation of the ultraviolet beam. Then, the energy of the ultraviolet beam and the ozone are used to dissolve and remove the smears.

The wet-type desmearing method, however, needs a long time to dissolve the smears in the alkaline solution. Also, the wet-type desmearing method requires a cleaning process and a neutralizing process after immersing the wiring substrate material in the alkaline solution. Furthermore, the wet-type desmearing method entails a waste solution treatment for the used alkaline solution. As such, the wet-type desmearing method has a problem, i.e., a considerably high cost is needed for the desmearing.

In recent years, there is a demand for forming a fine wiring pattern on the wiring substrate. Accordingly, there is a demand for forming via holes having smaller diameters. When the desmearing process is applied to the wiring substrate material that has small-diameter via holes, the alkaline solution does not penetrate into the via holes in a sufficient manner, and therefore it becomes difficult to reliably carry out the desmearing process in a desired manner.

On the contrary, the dry-type desmearing method can perform the desmearing process in a short time. Also, the dry-type desmearing method does not need the cleaning process and the neutralizing process to the wiring substrate material, and does not need the waste solution treatment. Thus, the dry-type desmearing method can reduce the cost that relates to the desmearing process. In addition, the dry-type desmearing method can deal with a wiring substrate material that has small-diameter via holes.

However, the inventors found that the conventional dry-type desmearing method had the following problem.

In the dry-type desmearing method, the smear that is derived from an organic substance (e.g., resin, which is a constituent element of the insulation layer(s)) is decomposed and removed by the energy of the ultraviolet beam and the action (effect) of the ozone. On the other hand, the smear that is derived from an inorganic substance (e.g., a metal, which is a constituent element of the conductive layer(s), and ceramics, which is a constituent element of a filler contained in the insulation layer(s)) is not decomposed by the ultraviolet beam and the action of the ozone, but remains on the wiring substrate material.

### LISTING OF REFERENCES

### Patent Literature Documents

PATENT LITERATURE DOCUMENT 1: Japanese Patent Application Laid-Open Publication No. 2002-217536

PATENT LITERATURE DOCUMENT 2: Japanese Patent Application Laid-Open Publication No. 8-180757

### SUMMARY OF THE INVENTION

### Problems to be Solved by the Invention

The present invention is proposed in view of the above-described facts. An object of the present invention is to provide a desmearing method that can reliably remove a smear even if the smear is derived from any of an inorganic substance and an organic substance, and another object is to provide a desmearing apparatus that carries out such desmearing method.

### Solution to the Problems

A desmearing method according to one aspect of the present invention is applied to a wiring substrate material having insulation layers and a conductive layer, laminated one after another. Each of the insulation layers is made from resin that contains a filler. The desmearing method includes:

a wet-type ultraviolet beam irradiating step of irradiating a treatment target portion of the wiring substrate material with an ultraviolet beam in a gas atmosphere while the treatment target portion is in a wet condition, the gas atmosphere including ozone and oxygen; and

a physical vibration applying step of applying physical vibrations to the wiring substrate material that has undergone the wet-type ultraviolet beam irradiating step. The treatment target portion is that portion of the wiring substrate material to which the wet-type ultraviolet beam irradiating step and the physical vibration applying step are applied.

Preferably, the desmearing method of the present invention includes, as a pre-treatment prior to the wet-type ultraviolet beam irradiating step, a wetting step of wetting the treatment target portion of the wiring substrate material. Preferably, the wetting step includes applying ultrasonic vibrations to the treatment target portion while the treatment target portion is in contact with water.

In the desmearing method of the present invention, it is preferred that a concentration of the ozone in the gas atmosphere prior to irradiating the wiring substrate material with the ultraviolet beam is equal to or greater than 0.1 volume %.

A desmearing apparatus according to an aspect of the present invention is configured to apply a desmearing process to a wiring substrate material. The wiring substrate material has insulation layers and a conductive layer, laminated one after another. Each of the insulation layers is made from resin that contains a filler. The desmearing apparatus includes:

a wetting unit configured to wet a treatment target portion of the wiring substrate material;

a wet-type ultraviolet beam irradiating unit configured to irradiate the treatment target portion of the wiring substrate material, which is made wet by the wetting unit, with an ultraviolet beam in a gas atmosphere, the gas atmosphere including ozone and oxygen; and

a physical vibration applying unit configured to apply physical vibrations to the wiring substrate material that has been irradiated with the ultraviolet beam by the wet-type ultraviolet beam irradiating unit.

In the desmearing apparatus of the present invention, the wetting unit preferably has an ultrasonic vibration applying unit configured to apply ultrasonic vibrations to the treatment target portion while the treatment target portion is in contact with water.

In the desmearing apparatus of the present invention, the wet-type ultraviolet beam irradiating unit preferably has an ozone generating unit configured to generate the ozone.

### Advantageous Effects of the Invention

The desmearing method according to one aspect of the present invention includes the wet-type ultraviolet beam irradiating step of irradiating the treatment target portion with the ultraviolet beam in the gas atmosphere, and the ozone and oxygen are present in the gas atmosphere. The desmearing method also includes the physical vibration applying step. Accordingly, it is possible to remove the smear(s) in a reliable manner even if the smear is any of the inorganic substance-based smear and the organic substance-based smear.

If the desmearing method of the present invention includes the pre-treatment step prior to the wet-type ultraviolet beam irradiating step in order to apply the ultrasonic vibrations to the treatment target portion with the treatment target portion being in contact with the water, then it is possible to sufficiently ensure that the treatment target portion is kept in the wet condition. Accordingly, it is possible to remove the organic substance-based smear in a more reliable manner.

The desmearing apparatus according to one aspect of the present invention can carry out the desmearing process by using the above-described desmearing method. Therefore, it is possible to remove the smear in a reliable manner even if the smear is any of the inorganic substance-based smear and the organic substance-based smear.

### BRIEF DESCRIPTION OF THE DRAWINGS

FIG. 1 is a cross-sectional view useful to describe a structure of major parts of an exemplary wiring substrate material, which is a target to be treated (processed) by a desmearing method according to one embodiment of the present invention.

FIG. 2 is a cross-sectional view useful to describe a method of fabricating the wiring substrate material shown in FIG. 1.

FIG. 3 is another cross-sectional view useful to describe the method of fabricating the wiring substrate material shown in FIG. 1.

FIG. 4 is still another cross-sectional view useful to describe the method of fabricating the wiring substrate material shown in FIG. 1.

FIG. 5 is a view useful to describe a step in an exemplary desmearing method according to an embodiment of the present invention.

FIG. 6 is a view useful to describe another step in the exemplary desmearing method according to the embodiment of the present invention.

FIG. 7 is a view useful to describe still another step in the exemplary desmearing method according to the embodiment of the present invention.

FIG. 8 is a view useful to describe yet another step in the exemplary desmearing method according to the embodiment of the present invention.

FIG. 9 is a view useful to describe another step in the exemplary desmearing method according to the embodiment of the present invention.

FIG. 10 is a cross-sectional view useful to schematically illustrate an exemplary configuration of a desmearing apparatus according to an embodiment of the present invention.

FIG. 11 is a cross-sectional view useful to schematically illustrate an exemplary configuration of a wet-type ultraviolet beam irradiating unit of a desmearing apparatus according to an embodiment of the present invention.

FIG. 12 is a cross-sectional view useful to schematically illustrate an exemplary configuration of another wet-type ultraviolet beam irradiating unit of a desmearing apparatus according to an embodiment of the present invention.

FIG. 13 is a cross-sectional view useful to schematically illustrate an exemplary configuration of another desmearing apparatus according to an embodiment of the present invention.

FIG. 14 is a cross-sectional view useful to schematically illustrate an exemplary configuration of an excimer lamp, which is used as a light source for emitting an ultraviolet beam having a wavelength equal to or shorter than 220 nm. FIG. 14 shows a lateral cross-sectional view taken along a longitudinal direction of a discharge vessel.

FIG. 15 is a cross-sectional view useful to schematically illustrate an exemplary configuration of the excimer lamp, which is used as the light source for emitting the ultraviolet beam having the wavelength equal to or shorter than 220 nm. FIG. 15 shows a cross-sectional view taken along the line A-A in FIG. 14.

### DETAILED DESCRIPTION OF EMBODIMENTS

Embodiments of the present invention will be described below.

### Wiring Substrate Material

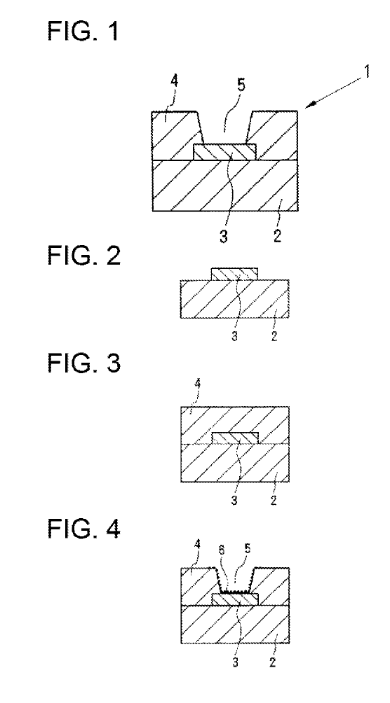

FIG. 1 is a cross-sectional view useful to describe a structure of major parts of an exemplary wiring substrate material, which is a target to be treated (processed) by a desmearing method according to one embodiment of the present invention.

The wiring substrate material 1 includes a first insulation layer 2, a conductive layer (wiring layer) 3 having a predetermined pattern and laminated on an upper surface of the first insulation layer 2, and a second insulation layer 4 laminated on the first insulation layer 2 and the conductive layer 3. A through hole 5, such as a via hole, is formed in the second insulation layer 4 such that the through hole 5 extends in the thickness direction of the second insulation layer 4. The through hole 5 exposes part of the conductive layer 3.

Each of the first insulation layer 2 and the second insulation layer 4 is made from resin that contains a filler. The filler is made from an inorganic substance.

The resin of each of the first insulation layer 2 and the second insulation layer 4 may be epoxy resin, bismaleimide triazine resin, polyimide resin, or polyester resin.

The material of the filler contained in each of the first insulation layer 2 and the second insulation layer 4 may be silica, alumina, mica, silicate, barium sulfate, magnesium hydroxide or titanium oxide. An average grain diameter of the filler is, for example, 0.1 to 3 μm.

A percentage of the filler in each of the first insulation layer 2 and the second insulation layer 4 is, for example, 20 to 60 mass %.

The thickness of the first insulation layer 2 is, for example, 20 to 800 μm. The thickness of the second insulation layer 4 is, for example, 10 to 50 μm. The diameter of the through hole 5 is, for example, 30 to 100 μm.

The material of the conductive layer 3 may be copper, nickel or gold.

The thickness of the conductive layer 3 is, for example, 10 to 100 μm.

The above-described wiring substrate material 1 is prepared, for example, in the following manner.

Firstly, as shown in FIG. 2, the conductive layer 3 having the predetermined pattern is formed on the upper surface of the first insulation layer 2. Subsequently, as shown in FIG. 3, the second insulation layer 4 is formed on the upper surface of the first insulation layer 2 and the conductive layer 3. Then, as shown in FIG. 4, the through hole 5 is formed at a predetermined position in the second insulation layer 4 such that the through hole 5 extends in the thickness direction of the second insulation layer 4.

It should be noted that the method of forming the conductive layer 3 is not limited to a particular method. For example, a subtractive process, a semi-additive process or the like may be employed as the method of forming the conductive layer 3.

The method of forming the second insulation layer 4 may include applying an insulation layer material, which contains liquid thermosetting resin and a filler in the liquid thermosetting resin, on the upper surface of the first insulation layer 2 and the conductive layer 3, and curing the insulation layer material. Alternatively, the method of forming the second insulation layer 4 may include bonding an insulation sheet, which contains a filler, on the upper surface of the first insulation layer 2 and the conductive layer 3 by means of thermocompression bonding or the like.

The method of forming the through hole 5 in the second insulation layer 4 may include drilling or laser beam machining. When the through hole 5 is prepared by the laser beam machining, a carbon dioxide gas laser device or a YAG laser device may be used.

When the wiring substrate material 1 is prepared in the above-described manner, a smear 6 that is produced upon forming the through hole 5 remains on the inner wall of the through hole 5 in the second insulation layer 4, on the upper surface of the second insulation layer 4 around the through hole 5, and the bottom of the through hole 5, i.e., that portion of the conductive layer 3 which are exposed by the through hole 5.

### Desmearing Method

In the desmearing method according to the embodiment of the present invention, a wet-type ultraviolet beam irradiating step is carried out. Specifically, a treatment target portion (area to be processed) of the wiring substrate material 1 is irradiated with an ultraviolet beam, with the treatment target portion being in a wet condition, in a gas atmosphere that contains ozone and oxygen. Then, a physical vibration applying step is carried out in the desmearing method. Specifically, physical vibrations are imparted to the wiring substrate material 1 that has undergone the wet-type ultraviolet beam irradiating step.

In the desmearing method according to the embodiment of the present invention, a pre-treatment is preferably carried out prior to the wet-type ultraviolet beam irradiating step.

The pre-treatment may include a step of improving wettability of the treatment target portion of the wiring substrate material 1 when the treatment target portion of the wiring substrate material 1 is not in the wet condition (wettability improving step), and also include a step of wetting the treatment target portion of the wiring substrate material 1 subsequent to the wettability improving step (wetting step).

### Wettability Improving Step

The wettability improving step may be carried out by irradiating the treatment target portion of the wiring substrate material with the ultraviolet beam, with the treatment target portion being in a no wet condition, i.e., dry-type ultraviolet beam irradiation process. Alternatively, the wettability improving step may be carried out by an atmospheric pressure plasma process, a reduced pressure plasma process, a corona discharge process or the like. Among these, the dry-type ultraviolet beam irradiation process is preferred.

The dry-type ultraviolet beam irradiation process is carried out, for example, in an atmosphere such as in the air that contains oxygen.

The ultraviolet beam to be directed to the wiring substrate material in the dry-type ultraviolet beam irradiation process has a wavelength equal to or shorter than 220 nm, and particularly preferably equal to or shorter than 190 nm. If the wavelength of the ultraviolet beam exceeds 220 nm, then it becomes difficult to reliably improve the wettability of the treatment target portion of the wiring substrate material.

The light source for the ultraviolet beam having a wavelength equal to or shorter than 220 nm may be a xenon excimer lamp (peak wavelength is 172 nm), a low pressure mercury lamp (bright line at 185 nm), a noble gas fluorescent lamp or the like.

The illuminance of the ultraviolet beam directed to the wiring substrate material is, for example, 10 to 200 mW/cm². The irradiation time of the ultraviolet beam to the wiring substrate material is, for example, 10 to 60 seconds. The irradiation time of the ultraviolet beam is appropriately decided on the basis of the illuminance of the ultraviolet beam and/or a condition of the remaining smear.

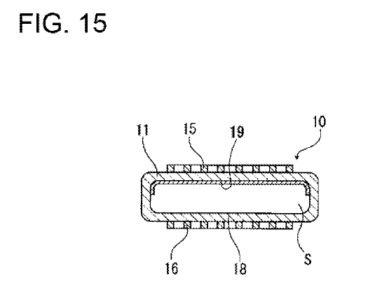

An example of the excimer lamp that is used as the light source for the ultraviolet beam having a wavelength equal to or shorter than 220 nm is, for example, an excimer lamp shown in FIGS. 14 and 15 (will be described).

### Wetting Step

The wetting step is carried out by, for example, immersing the wiring substrate material 1, which has undergone the wettability improving step, in the water. The immersing time is, for example, 10 to 60 seconds.

After the wiring substrate material is immersed in the water for a predetermined time, an unnecessary or surplus water may be removed from the treatment target portion of the wiring substrate material by, for example, an air knife.

In the wetting step, it is preferred that ultrasonic vibrations be applied to the treatment target portion, with the treatment target portion being in contact with the water. This is preferred because the treatment target portion (i.e., organic substance (resin) of the smear) sufficiently absorbs the water. As a result, a sufficient amount of OH radicals is generated in a subsequent wet-type ultraviolet beam irradiating step. The frequency of the ultrasonic wave is preferably 20 to 70 kHz if the water absorbing rate of the resin material in the insulation layer of the wiring substrate material is 2.0% or less (preferably 1.0% or less).

### Wet-Type Ultraviolet Beam Irradiating Step

In the wet-type ultraviolet beam irradiating step, the treatment target portion of the wiring substrate material 1, which has undergone the wetting step, is irradiated with the ultraviolet beam in a gas atmosphere. Ozone and oxygen are present in this gas atmosphere.

In the wet-type ultraviolet beam irradiating step, additional ozone is supplied. The additional ozone is a supplement to (is different from) the ozone produced upon irradiating the treatment target portion with the ultraviolet beam in the gas atmosphere including oxygen. Thus, the treatment target portion (or the wiring substrate material) is irradiated with the ultraviolet beam in the gas atmosphere in which the additional ozone is present. Specifically, the gas atmosphere is prepared with ozone being already present in the gas atmosphere. Then, the ultraviolet beam is emitted into the gas atmosphere. It should be noted that another additional ozone may be supplemented to the gas atmosphere while the ultraviolet beam is being emitted into the gas atmosphere.

For example, the ozone concentration in the gas atmosphere is preferably equal to or greater than 0.1 volume % before the wiring substrate material is irradiated with the ultraviolet beam, and more preferably 5 to 15 volume %.

It should be noted that nitrogen may be contained in the gas atmosphere. If nitrogen is contained in the gas atmosphere, the nitrogen concentration is preferably 0 to 60 volume %, for example.

In the wet-type ultraviolet beam irradiating step, the wavelength of the ultraviolet beam emitted to the wiring substrate material is preferably equal to or shorter than 220 nm, and particularly preferably equal to or shorter than 190 nm. If the wavelength of the ultraviolet beam is greater than 220 nm, it becomes difficult to decompose and remove the smear that is derived from an organic substance such as resin.

A light source for emitting the ultraviolet beam at the wavelength equal to or shorter than 220 nm may be a xenon excimer lamp (peak wavelength is 172 nm), a low pressure mercury lamp (bright line at 185 nm wavelength), a noble gas fluorescent lamp or the like.

The illuminance of the ultraviolet beam directed to the wiring substrate material 1 is, for example, 10 to 200 mW/cm². The irradiation time of the ultraviolet beam to the wiring substrate material 1 is appropriately decided depending upon the illuminance of the ultraviolet beam and a condition of the remaining smear. The irradiation time of the ultraviolet beam to the wiring substrate material 1 is, for example, 50 to 300 seconds.

An exemplary excimer lamp that may be used as the light source for emitting the ultraviolet beam at the wavelength equal to or shorter than 220 nm is an excimer lamp shown in FIGS. 14 and 15 (will be described).

### Physical Vibration Applying Step

In the physical vibration applying step, an ultrasonic vibration process is carried out to apply, for example, ultrasonic vibrations to the wiring substrate material 1, which has undergone the wet-type ultraviolet beam irradiation step. The frequency of the ultrasonic wave during the ultrasonic vibration process is preferably 20 to 70 kHz. If the frequency of the ultrasonic wave is greater than 70 kHz, it becomes difficult to destroy and separate the smear, which is derived from the inorganic substance, from the wiring substrate material.

In the ultrasonic vibration process, a vibration medium of the ultrasonic wave may be liquid such as water, or gas such as the air.

Specifically, when the water is used as the vibration medium, the wiring substrate material 1 is, for example, immersed in the water, and the water is caused to ultrasonically vibrate while the wiring substrate material 1 is immersed in the water. This is the ultrasonic vibration process. When the liquid is used as the vibration medium of the ultrasonic wave, the process time of the ultrasonic vibration process may be, for example, 10 to 600 seconds.

When the air is used as the vibration medium of the ultrasonic wave, the compressed air is caused to ultrasonically vibrate and blow against the wiring substrate material 1 to carry out the ultrasonic vibration process. Preferably, the pressure of the compressed air is equal to or greater than 0.2 MPa. The process time of the ultrasonic vibration process with the compressed air is, for example, 5 to 60 seconds.

In the desmearing method according to the embodiment of the present invention, the wetting step and the wet-type ultraviolet beam irradiating step may be repeated alternately before the physical vibration applying step is carried out.

How many times the wetting step and the wet-type ultraviolet beam irradiating step should be repeated may be appropriately decided on the basis of the irradiation time of the ultraviolet beam during each wet-type ultraviolet beam irradiating step. For example, the wetting step and the wet-type ultraviolet beam irradiating step are repeated once to five times.

With such approach, it is possible to keep the treatment target portion of the wiring substrate material in the wet condition. Thus, the smear that is derived from the organic substance is decomposed at a high efficiency during each wet-type ultraviolet beam irradiating step. As a result, it is possible to reduce a total time of the ultraviolet beam irradiation in the repeated wet-type ultraviolet beam irradiating steps.

It should be noted that although the wet-type ultraviolet beam irradiating step may be carried out once and then the physical vibration applying step may be carried out once, it is preferred that the wet-type ultraviolet beam irradiating step and the physical vibration applying step are carried out repeatedly and alternately.

How many times the wet-type ultraviolet beam irradiating step and the physical vibration applying step should be repeated may be appropriately decided on the basis of the irradiation time of the ultraviolet beam during each wet-type ultraviolet beam irradiating step and other factors. For example, the wet-type ultraviolet beam irradiating step and the physical vibration applying step are repeated once to five times.

An exemplary desmearing method according to the embodiment of the present invention will be described when the wet-type ultraviolet beam irradiating step and the physical vibration applying step are carried out twice respectively.

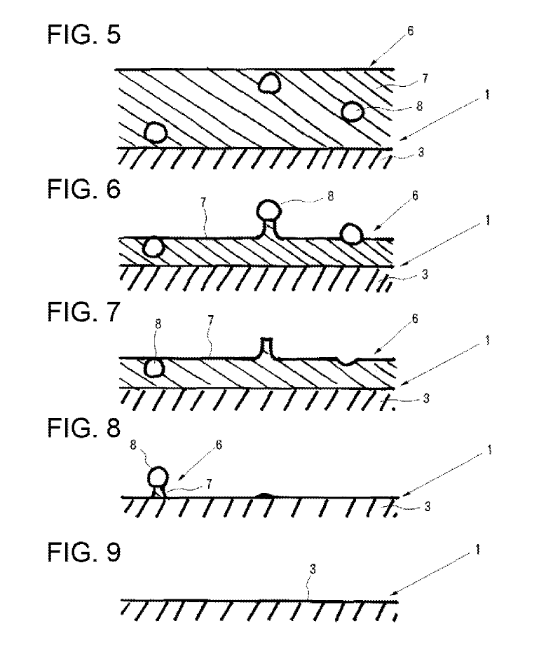

As shown in FIG. 5, the smear 6 is present on the treatment target portion (e.g., on the conductive layer 3) of the wiring substrate material 1 before the wet-type ultraviolet beam irradiating step is performed. The smear 6 is a combination of a smear 7 derived from an organic substance such as resin (hereinafter referred to as “organic substance-based smear”) and another smear 8 derived from an inorganic substance such as a filler (referred to as “inorganic substance-based smear”). The inorganic substance-based smear 8 is contained in the organic substance-based smear 7. The smear 6 is in the wet condition because the wetting step is performed.

As the treatment target portion of the wiring substrate material 1 is subjected to the ultraviolet beam irradiation process in a gaseous atmosphere including ozone and oxygen, part of the organic substance-based smear 7 is decomposed and gasified by the energy of the ultraviolet beam, the ozone produced upon the irradiation of the ultraviolet beam in the atmosphere including oxygen, OH radicals produced upon the irradiation of the ultraviolet beam in the wet condition, another OH radicals produced upon the reaction between the ozone and water, and the like. As a result, as shown in FIG. 6, part of the organic substance-based smear 7 is removed from the wiring substrate material 1. In the meantime, part of the inorganic substance-based smear 8 is exposed upon removal of part of the organic substance-based smear 7. The exposed inorganic substance-based smear 8 is irradiated with the ultraviolet beam, and therefore becomes fragile. The inventors assume that this is because the inorganic substance-based smear 8 shrinks and deforms upon being irradiated with the ultraviolet beam.

Subsequently, the wiring substrate material 1 is subjected to the physical vibration process such that the exposed inorganic substance-based smear 8 is destroyed by the mechanical action of the vibrations and separated (cleared away) from the wiring substrate material 1.

Also, the shrinkage of the inorganic substance-based smear 8 and a difference in the thermal expansions between the smears 7 and 8 produced upon irradiating the respective smears with the ultraviolet beam can possibly create a small gap between the organic substance-based smear 7 and the inorganic substance-based smear 8. Thus, the inorganic substance-based smear 8 is caused to leave the wiring substrate material 1 upon applying the physical vibration process.

Therefore, as shown in FIG. 7, part of the inorganic substance-based smear 8 is removed (separated) from the wiring substrate material 1.

Subsequently, the ultraviolet irradiation process is applied to the treatment target portion of the wiring substrate material 1 in the gas atmosphere that includes ozone and oxygen. As a result, most of the organic substance-based smear 7 is decomposed and gasified by the energy of the ultraviolet beam, the ozone produced upon irradiating the wiring substrate with the ultraviolet beam in the oxygen atmosphere, the OH radicals produced upon irradiating the wiring substrate material in the wet condition with the ultraviolet beam, the OH radicals produced upon the reaction between the ozone and the water, and the like. Therefore, as shown in FIG. 8, most of the organic substance-based smear 7 is removed from the wiring substrate material 1. In the meantime, the remaining part of the inorganic substance-based smear 8 is exposed as most of the remaining part of the organic substance-based smear 7 is removed. The exposed inorganic substance-based smear 8 is irradiated with the ultraviolet beam and becomes fragile.

After that, the physical vibration process is applied to the wiring substrate material 1 such that the exposed inorganic substance-based smear 8 is destroyed by the mechanical action of the vibrations and is caused to leave the wiring substrate material 1. In addition, a small gap may be created between the wiring substrate material 1 and the inorganic substance-based smear 8 by the shrinkage of the inorganic substance-based smear 8 and the thermal expansion difference between the smears 7 and 8 generated upon irradiating the smears 7 and 8 with the ultraviolet beam. As such, the inorganic substance-based smear 8 is separated from the wiring substrate material 1 by the physical vibration process. As a result, as shown in FIG. 9, the remaining part of the inorganic substance-based smear 8 is removed from the wiring substrate material 1, and the conductive layer 3 may be exposed.

In this manner, the desmearing method of this embodiment repeatedly and alternately carries out the wet-type ultraviolet beam irradiating step and the physical vibration applying step. Thus, it is possible to reduce a total time of the ultraviolet beam irradiation in the wet-type ultraviolet irradiating steps as compared to a desmearing method that carries out the wet-type ultraviolet beam irradiating step only once. If the desmearing method carries out the wet-type ultraviolet beam irradiating step only once, the decomposition of the smear by the ozone (active oxygen) takes place after the OH radicals disappear. The OH radicals have a faster decomposition speed than the ozone and the active oxygen. Thus, when the wet-type ultraviolet beam irradiating steps are repeated, it is possible to extend the time for the OH radical reaction, and reduce the total time of the ultraviolet beam irradiation.

According to the above-described desmearing method, it is possible to reliably remove any of the inorganic substance-based smear 8 and the organic substance-based smear 7 from the wiring substrate material 1.

The inventors assume that the above-described advantages are obtained because of the following reasons.

During the wet-type ultraviolet beam irradiating step, which is carried out in the gas atmosphere with the ozone being present in the gas atmosphere, the water is irradiated with the ultraviolet beam such that the OH radicals are generated. Also, the ozone reacts with the water to generate the OH radicals. Thus, the organic substance-based smear 7 is decomposed by the energy of the ultraviolet beam and the OH radicals during the wet-type ultraviolet beam irradiating step. In the above-described embodiment, the wiring substrate material is irradiated with the ultraviolet beam in the gas atmosphere with oxygen being present in the gas atmosphere, and therefore the ozone is generated. In addition to this ozone, a supplementary ozone is supplied. Thus, a larger amount of OH radicals is generated than a case where no ozone is supplemented. Consequently, it is possible to decompose the organic substance-based smear 7 in a shorter time. In the wet-type ultraviolet beam irradiating step, the inorganic substance-based smear 8 is not decomposed, and remains on the wiring substrate material 1. However, the inorganic substance-based smear 8 is irradiated with the ultraviolet beam and becomes fragile. Thus, the physical vibration applying step is performed after the wet-type ultraviolet beam irradiating step. The physical vibration applying step applies the physical vibrations to the wiring substrate material 1 to destroy the inorganic substance-based smear 8. Accordingly, the inorganic substance-based smear 8 is forced to leave the wiring substrate material 1.

The wetting step is carried out as the pre-treatment prior to the wet-type ultraviolet beam irradiating step. In the wetting step, the ultrasonic vibrations are applied to the wiring substrate material with the treatment target portion being in contact with the water. Thus, it is possible to ensure that the treatment target portion (more specifically, the organic substance-based smear 7 (resin)) is in the wet condition. Accordingly, a sufficient amount of OH radicals is generated in the wet-type ultraviolet beam irradiating step, and it is possible to remove the smear 6 in a more reliable manner. Because the ultrasonic vibrations cause the water to penetrate into the organic substance-based smear 7 (resin), i.e., the water is deeply absorbed by the organic substance-based smear 7, it is still possible to generate new OH radicals in a wet area at deep(er) positions, even after the surface of the smear is decomposed. This contributes to the reduction in the ultraviolet beam irradiation time.

### Desmearing Apparatus

The desmearing apparatus of this embodiment is an apparatus for carrying out the above-described desmearing process. The desmearing apparatus includes a wetting unit for wetting the treatment target portion of the wiring substrate material, a wet-type ultraviolet beam irradiating unit for irradiating the treatment target portion of the wiring substrate material, which is subjected to the wetting process, with the ultraviolet beam in the gas atmosphere in which ozone and oxygen are present, and a physical vibration applying unit for applying physical vibrations to the wiring substrate material which is subjected to the wet-type ultraviolet beam irradiation process.

Preferably, an ultrasonic vibration applying device is attached to the wetting unit of the desmearing apparatus of this embodiment such that the ultrasonic vibration applying device can apply ultrasonic vibrations to the treatment target portion while the treatment target portion is in contact with the water. It is also preferred that an ozone generating device for generating ozone may be attached to the wet-type ultraviolet beam irradiating unit.

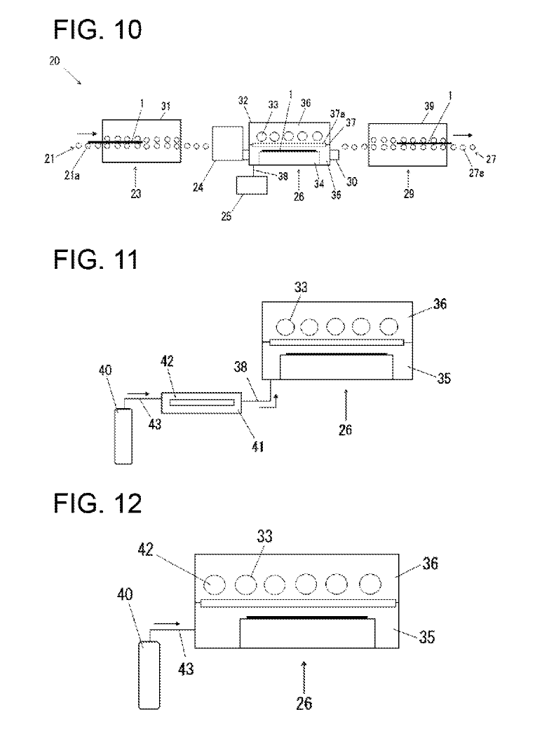

FIG. 10 is a cross-sectional view that schematically shows an exemplary configuration of the desmearing apparatus of this embodiment.

The desmearing apparatus 20 includes a wet-type ultraviolet beam irradiating unit 26. The wet-type ultraviolet beam irradiating unit 26 has an ultraviolet lamp 33 for irradiating the wiring substrate material 1 with the ultraviolet beam, an ozone generating device 25 for generating ozone, and an oxygen source (not shown) for feeding oxygen. A wetting unit 23 for wetting the treatment target portion of the wiring substrate material 1 is disposed upstream of the wet-type ultraviolet beam irradiating unit 26. A physical vibration applying unit 29 that has a physical vibration applying unit (not shown) is disposed downstream of the wet-type ultraviolet beam irradiating unit 26.

A stocker 24 is disposed between the wetting unit 23 and the wet-type ultraviolet beam irradiating unit 26. The stocker 24 receives and stores the wiring substrate material 1 after the wetting process is applied to the wiring substrate material 1 by the wetting unit 23.

The wetting unit 23 has a water tank 31 for reserving water. The ultrasonic vibration applying unit (not shown) is attached to or associated with the water tank 31 such that the ultrasonic vibration applying unit applies ultrasonic vibrations to the water tank 31, with the water being a vibration medium. For example, the ultrasonic vibration applying unit has an ultrasonic oscillator.

A first conveyance device 21 that has a plurality of conveyance rollers 21a is disposed in the wetting unit 23. The first conveyance device 21 conveys the wiring substrate material 1 into the water tank 31, and conveys the wiring substrate material 1 to the stocker 24 from the water tank 31.

The wet-type ultraviolet irradiating unit 26 has a housing 32. In the housing 32, disposed are a plurality of ultraviolet lamps 33. In the illustrated embodiment, there are five ultraviolet lamps 33. The ultraviolet lamps 33 are arranged in a single plane such that the lamp axes of the ultraviolet lamps 33 extend in parallel to each other. Each of the ultraviolet lamps 33 emits an ultraviolet beam at a wavelength preferably equal to or shorter than 220 nm and more preferably equal to or shorter than 190 nm.

A treatment chamber (process chamber) 35 is defined in the housing 32. The treatment chamber 35 has a bed or table 34, on which the wiring substrate material 1 is placed. A lamp chamber 36 is defined above the treatment chamber 35. The ultraviolet lamps 33 are disposed in the lamp chamber 36. The treatment chamber 35 is partitioned (separated) from the lamp chamber 36 by a partition wall 37. Part of the partition wall 37 is formed by a light-transmitting window 37a that allows the ultraviolet beam to pass through the window 37a.

An ozone generating device 25 is connected to the treatment chamber 35 by a conduit 38. For example, the ozone generating device 25 has an ozonizer. Also, an oxygen source (not shown) is connected to the treatment chamber 35 at a position upstream of the ozone generating device 25 by another conduit (not shown).

Ozone generated by the ozone generating device 25 and oxygen supplied from the oxygen source (not shown) are introduced into the treatment chamber 35. Thus, the atmosphere in the treatment chamber 35 is a gas atmosphere in which the ozone and oxygen are present. It should be noted that nitrogen may be contained in the treatment chamber 35.

The concentration of the ozone in the treatment chamber 35 is, for example, 0.1 to 15 volume % before the ultraviolet beam is emitted to the treatment chamber 35.

The wet-type ultraviolet beam irradiating unit 26 has a conveyance robot 30 that conveys the wiring substrate material 1 to the table 34 from the stocker 24, and also conveys the wiring substrate material 1 to a second conveyance device 27 from the table 34.

The physical vibration applying unit 29 has a water tank 39 that reserves water, and a physical vibration applying device (not shown) that applies ultrasonic vibrations to the wiring substrate material with the water being a vibration medium. The physical vibration applying device is disposed in the water tank 39 and has an ultrasonic oscillator.

The physical vibration applying unit 29 includes a second conveyance device 27 that has a plurality of conveyance rollers 27a. The second conveyance device 27 conveys the wiring substrate material 1, which is conveyed by the conveyance robot 30, into the water tank 39. The second conveyance device 27 also conveys the wiring substrate material 1 out of the water tank 39.

The desmearing process is performed by the above-described desmearing apparatus 20 in the following manner.

Firstly, the wiring substrate material 1 is conveyed into the water tank 31 by the first conveyance device 21, and the wiring substrate material 1 is immersed in the water. The ultrasonic vibration applying unit (not shown) applies the ultrasonic vibrations to the wiring substrate material 1 while the wiring substrate material 1 is being immersed in the water. As such the wetting process is carried out. After the wetting process, the wiring substrate material 1 is conveyed to the stocker 24 by the first conveyance device 21, and stored in the stocker 24.

The wiring substrate material 1 is conveyed onto the table 34 from the stocker 24 by the conveyance robot 30. Then, the ozone generated by the ozone generating device 25 is introduced into an upstream portion of the treatment chamber 35 via the first conduit 38, and oxygen is introduced into the upstream portion of the treatment chamber 35 from the oxygen source (not shown). Thus, oxygen and ozone flow from the upstream portion (area) to the downstream portion (area) in the treatment chamber 35, and the interior of the treatment chamber 35 becomes a gas atmosphere in which oxygen and ozone are present. In this condition, the wiring substrate material 1 is irradiated with the ultraviolet beams from the ultraviolet lamps 33. Thus, the wet-type ultraviolet beam irradiation process is carried out.

After the ultraviolet beam irradiation process, the wiring substrate material 1 is conveyed into the second water tank 39 by the second conveyance device 27. The ultrasonic vibrations are applied to the wiring substrate material 1 by the physical vibration applying device (not shown) while the wiring substrate material 1 is being immersed in the water. Thus, the physical vibration process is carried out.

The above-described desmearing apparatus 20 carries out the desmearing method of this embodiment to perform the desmearing process. Accordingly, it is possible to reliably remove the smear, regardless of the smear being derived from the inorganic substance and the smear being derived from the organic substance.

It should be noted that the present invention is not limited to the above-described embodiment. Any suitable changes and modifications may be made to the above-described embodiment.

For example, as shown in FIG. 11, the ozone generating device may include an oxygen source 40 and an ultraviolet lamp device 41. The ultraviolet lamp device 41 has an ultraviolet lamp 42 used for generating ozone. In this ozone generating device, the oxygen source 40 is connected to the ultraviolet lamp device 41 via a conduit 43. The ultraviolet lamp device 41 is connected to the treatment chamber 35 of the wet-type ultraviolet beam irradiating unit 26 via another conduit 38.

With such ozone generating device, the oxygen from the oxygen source 40 is supplied to the ultraviolet lamp device 41 through the conduit 43. The supplied oxygen is transformed to ozone by the ultraviolet beam from the ozone generation ultraviolet lamp 42. The resulting ozone is introduced into the treatment chamber 35 through the conduit 38.

Alternatively, the ozone generating device may be integral with the wet-type ultraviolet beam irradiation unit. Specifically, as shown in FIG. 12, the ozone generation ultraviolet lamp 42 is disposed in the lamp chamber 36 such that the ozone generation ultraviolet lamp 42 is located at a position upstream of the most upstream one of the ultraviolet lamps 33. The oxygen source 40 is connected to the treatment chamber 35 via the conduit 43 such that oxygen is introduced to the upstream space in the treatment chamber 35.

With such ozone generating device, oxygen is supplied to the upstream space in the treatment chamber 35 from the oxygen source 40. The supplied oxygen is transformed to the ozone as the oxygen is irradiated with the ultraviolet beam from the ozone generation ultraviolet lamp 42. The resulting ozone is introduced to the downstream space in the treatment chamber 35.

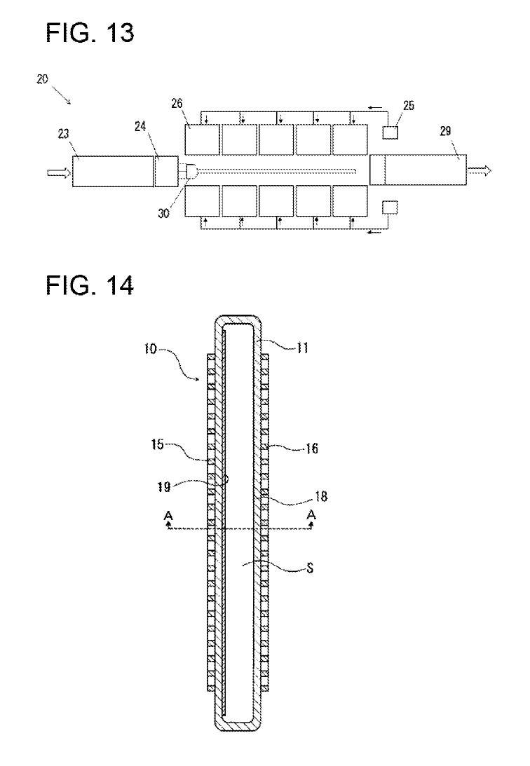

Alternatively, as depicted in FIG. 13, there may be provided a plurality of wet-type ultraviolet beam irradiation units 26, each of which is similar to the wet-type ultraviolet beam irradiation unit 26 shown in FIG. 10. The wiring substrate material 1 may be processed simultaneously by these parallel wet-type ultraviolet beam irradiation units 26.

Each of the ultraviolet lamps used in the desmearing apparatus of this embodiment may be any suitable lamp that can emit an ultraviolet beam at a wavelength equal to or shorter than 220 nm. In the following description, an exemplary configuration of the ultraviolet lamp will be described.

FIG. 14 is a lateral cross-sectional view of an excimer lamp 10 taken along a longitudinal direction of a discharge vessel 11 of the excimer lamp 10. FIG. 14 illustrates a schematic configuration of the excimer lamp 10, which is used as a light source of the ultraviolet beam having a wavelength equal to or less than 220 nm. FIG. 15 is a cross-sectional view taken along the line A-A in FIG. 14.

The excimer lamp 10 includes the discharge vessel 11 that is air tightly sealed or plugged at opposite ends thereof. The discharge vessel 11 is a hollow vessel and has an elongated shape. The discharge vessel 11 defines the discharge space S therein. The cross-sectional shape of the discharge vessel 11 is rectangular. A discharge gas is sealed in the discharge vessel 11. For example, the discharge gas is a xenon gas, or a mixture of argon and chlorine.

The discharge vessel 11 is made from silica glass (e.g., synthetic silica glass) that properly transmits a vacuum ultraviolet beam therethrough, and serves as a dielectric.

A pair of grid-shaped electrodes 15 and 16 are disposed on the discharge vessel 11. Specifically, the electrode 15 that serves as a high voltage feeding electrode is disposed on an outer surface of the long-side face of the discharge vessel 11, and the other electrode 16 that serves as a grounding electrode is disposed on the outer surface of the opposite long-side face of the discharge vessel 11. The electrodes 15 and 16 extend in the longitudinal direction of the discharge vessel 11. Thus, the discharge vessel 11, which serves as the dielectric, is sandwiched between the two electrodes 15 and 16.

The electrodes 15 and 16 may be formed by applying a paste of metal (electrode material) on the discharge vessel 11, or by printing.

As an electric power for lighting is fed to the electrode 15 of the excimer lamp 10, a discharge takes place across the electrodes 15 and 16 via the wall of the discharge vessel 11, which serves as the dielectric. This creates excimer molecules, and results in an excimer discharge, i.e., a vacuum ultraviolet beam is emitted from the excimer molecules. In order to efficiently utilize the vacuum ultraviolet beam, which is generated by the excimer discharge, an ultraviolet beam reflection film 19 is disposed on an inner surface of the discharge vessel 11. The ultraviolet beam reflection film 19 is made from silica particles and alumina particles. When the xenon gas is used as the discharge gas, the vacuum ultraviolet beam that has a peak at a wavelength of 172 nm is emitted. When a mixture of argon and chlorine is used as the discharge gas, the vacuum ultraviolet beam that has a peak at a wavelength of 175 nm is emitted.

The ultraviolet beam reflection film 19 may extend on that inner surface of the long-side face of the discharge vessel 11 which corresponds to the high voltage feeding electrode 15 and may also extend on that part of the inner surface of a short-side face which is continuous from the inner surface of the long-side face. A light emission part (aperture part) 18 is formed on that inner surface of the long-side face of the discharge vessel 11 which corresponds to the other electrode (grounding electrode) 16 and which has no ultraviolet reflection layer 19.

For example, the thickness of the ultraviolet beam reflection film 19 is preferably 10 to 100 μm.

Because the silica particles and the alumina particles of the ultraviolet beam reflection film 19 have a high refractive index and transmit the vacuum ultraviolet beam, some part of the vacuum ultraviolet beam that arrives at the silica particles or the alumina particles is reflected by the surfaces of the particles and some part of the vacuum ultraviolet beam refracts and is incident to the interior of the particles. Most of the light incident to the interior of the particles is transmitted through the particles (and some part is absorbed by the ultraviolet beam reflection film 19). The transmitted light refracts again when it is emitted to the outside from the ultraviolet beam reflection film 19. Such reflection and refraction take place repeatedly. In other words, the ultraviolet beam reflection film 19 allows the diffusion reflection to take place.

Furthermore, because the ultraviolet beam reflection film 19 is made from the silica particles and/or the alumina particles, i.e., ceramics, the ultraviolet beam reflection film 19 does not generate impurity gases, and can stand the discharge (does not break due to the discharge).

The silica particles of the ultraviolet beam reflection film 19 may be fine particles that are prepared by pulverizing silica glass.

The particle diameter of the silica particles may be between 0.01 to 20 pm when the particle diameter is defined as indicated below. For example, a center (dominant) particle diameter (i.e., peak value of number average particle diameters) is preferably 0.1 to 10 μm and more preferably 0.3 to 3 μm.

Preferably, a percentage of the silica particles having the center particle diameter is equal to or greater than 50%.

The particle diameter of the alumina particles that form the ultraviolet beam reflection film 19 may be between 0.1 to 10 μm when the particle diameter is defined as indicated below. For example, a center particle diameter (i.e., peak value of number average particle diameters) is preferably 0.1 to 3 μm and more preferably 0.3 to 1 μm.

Preferably, a percentage of the alumina particles having the center particle diameter is equal to or greater than 50%.

The “particle diameter” is a Feret diameter in this specification. In order to measure the Feret diameter, an observation area is decided on a surface that is obtained by fracturing (breaking) the ultraviolet beam reflection film 19 in a direction perpendicular to the surface of the ultraviolet beam reflection film 19. An approximate center area on this fracture surface when viewed in the thickness direction of the ultraviolet beam reflection film is used as the observation area. In this observation area, the Feret diameter is measured by obtaining an image of enlarged-projection with an SEM (scanning electron microscope), sandwiching an arbitrary particle in the enlarged-projection image by two parallel lines extending in a predetermined direction, and measuring the distance between the two parallel lines. This distance is the Feret diameter.

In order to obtain the “center particle diameter,” a certain number of particle diameters (Feret diameters) are prepared. Then, the range from the minimum value to the maximum value of the particle diameters is divided into a plurality of subranges (segments) (e.g., fifteen subranges). Each subrange is a 0.1 μm width. The “center particle diameter” is a center value of that subrange which has the largest number (frequency) of particles therein, out of the fifteen subranges.

### EXAMPLES

Now, concrete examples of this invention will be described. It should be noted that the present invention is not limited to such examples.

### Preparation of Sample Wiring Substrate Materials

A lamination of a copper foil and an insulation layer was prepared. The insulation layer was formed on the copper foil.

The thickness of the copper foil was 100 μm, and the thickness of the insulation layer was 100 μm. The insulation layer was made from epoxy resin, with silica being contained in the epoxy resin at 40 mass %. The average particle diameter of silica was 1.0 μm.

The laser beam machining was applied to the insulation layer of this lamination by a CO₂ gas laser device to create a through hole in the insulation layer. The diameter of the through hole was 50 μm. In this manner, a sample wiring substrate material was prepared. A bottom of the through hole of the sample wiring substrate material was observed with the scanning electron microscope, and a smear was found on the bottom of the through hole.

### Example 1

The wettability improving step and the wetting step were applied to the sample wiring substrate material in a manner which will be described below.

### (1) Wettability Improving Step

In the air, a dry-type ultraviolet beam irradiation process was applied to the interior of the through hole of the sample wiring substrate material by an ultraviolet irradiation device that had a xenon excimer lamp, under the following conditions.

### Conditions of Dry-Type Ultraviolet Beam Irradiation Process:

Ultraviolet beam illuminance at an outer surface of the ultraviolet beam emission window of the ultraviolet beam irradiating device was 40 W/cm².

Distance between the ultraviolet beam emission window of the ultraviolet beam irradiation device and the sample wiring substrate material was 3 mm.

Ultraviolet beam irradiation time was 60 seconds.

### (2) Wetting Step

The sample wiring substrate material was immersed in the pure water for three minutes while applying ultrasonic waves of 40 kHz to the sample wiring substrate material to cause the sample wiring substrate material to ultrasonically vibrate.

Subsequently, the ultraviolet beam irradiation step and the physical vibration applying step were applied to the sample wiring substrate material in the following manner to apply the desmearing process to the sample wiring substrate material.

### (3) Ultraviolet Beam Irradiation Step

Ozone and oxygen were supplied to the gas atmosphere under the following conditions such that ozone and oxygen were present in the gas atmosphere. Then, the ultraviolet beam irradiation process was applied to the interior of the through hole of the sample wiring substrate material by the ultraviolet beam irradiation device having the xenon excimer lamp under the following conditions.

### Conditions of Ultraviolet Beam Irradiation:

Ultraviolet beam illuminance at the outer surface of the ultraviolet beam emission window of the ultraviolet beam irradiating device was 40 W/cm².

Distance between the ultraviolet beam emission window of the ultraviolet beam irradiation device and the sample wiring substrate material was 0.5 mm.

Ultraviolet beam irradiation time was 150 seconds.

### Conditions of Gas Atmosphere:

Ozone concentration was 5 volume %.

Oxygen concentration was 95 volume %.

### (4) Physical Vibration Applying Step

Upon completing the ultraviolet beam irradiation step (3), the sample wiring substrate material was immersed in the pure water. With the sample wiring substrate material being in the pure water, the ultrasonic vibration process was applied to the sample wiring substrate material for three minutes. The ultrasonic vibration process was performed with ultrasonic waves of 40.0 kHz.

### Evaluation 1

After the desmearing process, the bottom of the sample wiring substrate material was observed with the scanning electron microscope to evaluate the remaining state (condition) of the smear derived from the resin (i.e., organic substance-based smear) and the remaining state of another smear derived from the filler (i.e., inorganic substance-based smear) with the following criteria.

A: No remaining smear observed

B: Large amount of remaining smear observed

The results are shown in Table 1.

### Comparative Example 1

The desmearing process was applied to the sample wiring substrate material in the following manner.

In the air, an ultraviolet beam irradiation process was applied to the interior of the through hole of the sample wiring substrate material by an ultraviolet irradiation device that had a xenon excimer lamp, under the following conditions. After the ultraviolet beam irradiation process, the sample wiring substrate material was cleaned by a high pressure flow of water. After the desmearing process, the sample wiring substrate material was evaluated in a similar manner to Example 1. The results are also indicated in Table 1.

### Conditions of Ultraviolet Beam Irradiation:

Ultraviolet beam illuminance at the outer surface of the ultraviolet beam emission window of the ultraviolet beam irradiating device was 40 W/cm².

Distance between the ultraviolet beam emission window of the ultraviolet beam irradiation device and the sample wiring substrate material was 0.5 mm.

Ultraviolet beam irradiation time was 150 seconds.

TABLE 1

| | UV | Physical | Remaining Smear | |
|---|---|---|---|---|
| | Irradiation | Vibration | Organic | Inorganic |
| | Process | Process | Smear | Smear |
| Example 1 | Applied | Applied | A | A |
| Comparison 1 | Applied | Not applied | A | B |

As obvious from the results indicated in Table 1, it was confirmed that the desmearing method of Example 1 could remove the inorganic substance-based smear and the organic substance-based smear from the wiring substrate material in a reliable manner.

### Example 2

The wettability improving step and the wetting step were applied to the sample wiring substrate material in a manner which will be described below.

### (1) Wettability Improving Step

In the air, a dry-type ultraviolet beam irradiation process was applied to the interior of the through hole of the sample wiring substrate material by an ultraviolet irradiation device that had a xenon excimer lamp, under the following conditions.

### Conditions of Dry-Type Ultraviolet Beam Irradiation Process:

Ultraviolet beam illuminance at an outer surface of the ultraviolet beam emission window of the ultraviolet beam irradiating device was 40 W/cm².

Distance between the ultraviolet beam emission window of the ultraviolet beam irradiation device and the sample wiring substrate material was 3 mm.

Ultraviolet beam irradiation time was 60 seconds.

### (2) Wetting Step

The sample wiring substrate material was immersed in the pure water for three minutes while applying ultrasonic waves of 40 kHz to the sample wiring substrate material to cause the sample wiring substrate material to ultrasonically vibrate.

Subsequently, the ultraviolet beam irradiation step and the physical vibration applying step were carried out to the sample wiring substrate material in the following manner to apply the desmearing process to the sample wiring substrate material.

### (3) Ultraviolet Beam Irradiation Step

Ozone and oxygen were supplied to the gas atmosphere under the following conditions such that ozone and oxygen were present in the gas atmosphere. Then, the ultraviolet beam irradiation process was applied out to the interior of the through hole of the sample wiring substrate material by the ultraviolet beam irradiation device having the xenon excimer lamp under the following conditions.

### Conditions of Ultraviolet Beam Irradiation:

Ultraviolet beam illuminance at the outer surface of the ultraviolet beam emission window of the ultraviolet beam irradiating device was 40 W/cm².

Distance between the ultraviolet beam emission window of the ultraviolet beam irradiation device and the sample wiring substrate material was 0.5 mm.

### Conditions of Gas Atmosphere:

Ozone concentration was 5 volume %.

Oxygen concentration was 95 volume %.

### (4) Physical Vibration Applying Step

Upon completing the ultraviolet beam irradiation step (3), the sample wiring substrate material was immersed in the pure water. With the sample wiring substrate material being in the pure water, the ultrasonic vibration process was applied to the sample wiring substrate material for three minutes. The ultrasonic vibration process was performed with ultrasonic waves of 40.0 kHz.

### Evaluation 2

The ultraviolet beam irradiation time in the ultraviolet beam irradiation step was only changed stepwise from 50 seconds to 600 seconds in the above-described desmearing process. Upon finishing the desmearing process, the bottom of the sample wiring substrate material was observed with the scanning electron microscope to evaluate the condition of the remaining smear. The evaluation was made on the basis of the ultraviolet beam irradiation time spent till the smear disappeared. The results are shown in Table 2. In Table 2, “A” indicates that the ultraviolet beam irradiation process was conducted in an ozone atmosphere. “B” indicates that the ultraviolet beam irradiation process was conducted in a no ozone atmosphere.

### Comparative Example 2

The desmearing process was applied to the sample wiring substrate material in a similar manner to Example 2 except that the wetting step was not conducted. The condition of the remaining smear was evaluated in the same manner as Example 2. The results are indicated in Table 2.

### Comparative Example 3

The desmearing process was applied to the sample wiring substrate material in a similar manner to Example 2 except that no ozone was supplied during the ultraviolet beam irradiation step. The condition of the remaining smear was evaluated in the same manner as Example 2. The results are indicated in Table 2.

### Reference Example 1

The desmearing process was applied to the sample wiring substrate material in a similar manner to Example 2 except that the wetting step was not conducted and no ozone was supplied during the ultraviolet beam irradiation step. The condition of the remaining smear was evaluated in the same manner as Example 2. The results are indicated in Table 2.

TABLE 2

| | Wetting | In Ozone | Irradiation |
|---|---|---|---|
| | Process | Atmosphere | Time (sec) |
| Example 2 | Applied | A | 150 |
| Comparison 2 | Not applied | A | 400 |
| Comparison 3 | Applied | B | 350 |
| Reference 1 | Not applied | B | 600 |

As obvious from the results indicated in Table 2, it was confirmed that the desmearing process of Example 2 had a shorter time of the ultraviolet beam irradiation needed to remove the smears than Comparative Examples 2 and 3 and Reference Example 1.

The inventors assume that the above-described advantages are obtained because of the following reasons. In the desmearing method of Reference Example 1, the treatment target portion is directly irradiated with the ultraviolet beam to decompose the smears. Also, the oxygen atmosphere is irradiated with the ultraviolet beam to generate ozone, and the resulting ozone also decomposes the smears. As such, the desmearing method of Reference Example 1 relies upon the direct decomposition of the smears with the ultraviolet beam and the decomposition of the smears with the ozone.

Similar to Reference Example 1, the desmearing method of Comparative Example 2 relies upon the direct decomposition of the smears with the ultraviolet beam and the decomposition of the smears with the ozone. In addition, the atmosphere that contains ozone in advance is irradiated with the ultraviolet beam. Thus, as compared to Reference Example 1, an amount of ozone to be used in decomposing the smears increases, and the decomposition of the smears with the ozone is enhanced. Accordingly, the inventors assume that Comparative Example 2 reduces the ultraviolet beam irradiation time as compared to Reference Example 1.

Similar to Reference Example 1, the desmearing method of

Comparative Example 3 relies upon the direct decomposition of the smears with the ultraviolet beam and the decomposition of the smears with the ozone. Furthermore, the treatment target portion is irradiated with the ultraviolet beam while the treatment target portion is in the wet condition. Thus, OH radicals are generated. The resulting OH radicals also decompose the smears. Thus, the desmearing method of Comparative Example 3 decomposes the smears by means of the direct decomposition with the ultraviolet beam, the decomposition with the ozone, and the decomposition with the

OH radicals. Because the OH radicals have a greater oxidizing power than the ozone, the smears are decomposed in a shorter time. Therefore, it can be said that the ultraviolet beam irradiation time of Comparative Example 3 is reduced, as compared to Comparative Example 2.

On the contrary, the desmearing method of Example 2 relies upon the direct decomposition of the smears with the ultraviolet beam, the decomposition of the smears with the ozone and the decomposition of the smears with the OH radicals. This is similar to Comparative Example 3. In addition, the atmosphere that contains the ozone in advance is irradiated with the ultraviolet beam such that the ozone reacts with the water to produce OH radicals in Example 2. The resulting OH radicals also decompose the smears. As such, the desmearing method of Example 2 enhances the decomposition of the smears with the OH radicals, as compared to Comparative Example 3. Therefore, Example 2 can reduce the ultraviolet beam irradiation time as compared to Comparative Example 3.

As described above, the desmearing method of Example 2 removed the smears with the ultraviolet beam in a shorter time because the smears were directly decomposed by the ultraviolet beam, decomposed by the ozone, and decomposed by the enhanced (increased) OH radicals.

### REFERENCE NUMERALS AND SYMBOLS

1: Wiring substrate material

2: First insulation layer

3: Conductive layer

4: Second insulation layer

5: Through hole

6: Smear

7: Organic smear

8: Inorganic smear

10: Excimer lamp

11: Discharge vessel

15: One electrode

16: The other electrode

18: Light emitting part

19: Ultraviolet beam reflection film

20: Desmearing apparatus

21: Conveyance device

21a: Conveyance roller

23: Wetting unit

24: Stocker

25: Ozone generating device

26: Wet-type ultraviolet beam irradiating unit

27: Conveyance device

27a: Conveyance roller

29: Physical vibration applying unit

30: Conveyance robot

31: Water tank

32: Housing

33: Ultraviolet lamp

34: Support

35: Processing room

36: Lamp chamber

37: Partition wall

37a: Light transmitting window

38: Conduit

39: Water vessel

40: Oxygen source

41: Ultraviolet lamp device

42: Ultraviolet lamp used to generate ozone

43: Conduit

S: Discharge space

1. A desmearing method to be applied to a wiring substrate material having insulation layers and a conductive layer laminated on one of the insulation layers, each of the insulation layers being made from resin that contains a filler, the desmearing method comprising:
a wet-type ultraviolet beam irradiating step of irradiating a treatment target portion of the wiring substrate material with an ultraviolet beam in a gas atmosphere while the treatment target portion being in a wet condition, said gas atmosphere including ozone and oxygen; and
a physical vibration applying step of applying physical vibrations to the wiring substrate material that has undergone the wet-type ultraviolet beam irradiating step.

2. The desmearing method according to claim 1 further comprising, as a pre-treatment prior to the wet-type ultraviolet beam irradiating step, a wetting step of wetting the treatment target portion of the wiring substrate material, and wherein the wetting step includes applying ultrasonic vibrations to the wiring substrate material while the treatment target portion is in contact with water.

3. The desmearing method according to claim 1, wherein a concentration of the ozone in the gas atmosphere prior to irradiating the wiring substrate material with the ultraviolet beam in the wet-type ultraviolet beam irradiating step is equal to or greater than 0.1 volume %.

4. A desmearing apparatus configured to apply a desmearing process to a wiring substrate material, the wiring substrate material having insulation layers and a conductive layer laminated on one of the insulation layers, each of the insulation layers being made from resin that contains a filler, said desmearing apparatus comprising:
a wetting unit configured to wet a treatment target portion of the wiring substrate material;
at least one wet-type ultraviolet beam irradiating unit configured to irradiate the treatment target portion of the wiring substrate material, which is made wet by the wetting unit, with an ultraviolet beam in a gas atmosphere, the gas atmosphere including ozone and oxygen; and
a physical vibration applying unit configured to apply physical vibrations to the wiring substrate material that has been irradiated with the ultraviolet beam by the wet-type ultraviolet beam irradiating unit.

5. The desmearing apparatus according to claim 4, wherein the wetting unit has an ultrasonic vibration applying unit configured to apply ultrasonic vibrations to the treatment target portion while the treatment target portion is in contact with water.

6. The desmearing apparatus according to claim 4, wherein the wet-type ultraviolet beam irradiating unit has an ozone generating unit configured to generate the ozone.

7. The desmearing method according to claim 1, wherein the treatment target portion includes at least one of a first smear derived from an organic substance and a second smear derived from an inorganic smear.

8. The desmearing method according to claim 1 further comprising a step of improving wettability of the treatment target portion of the wiring substrate material.

9. The desmearing method according to claim 1 further comprising a pre-treatment step of irradiating the treatment target portion of the wiring substrate material with an ultraviolet beam while the treatment target portion being in a dry condition, said pre-treatment step being carried out prior to said wet-type ultraviolet beam irradiating step.

10. The desmearing method according to claim 1, wherein the ultraviolet beam has a wavelength equal to or shorter than 220 nm.

11. The desmearing method according to claim 1, wherein said physical vibration applying step applies ultrasonic vibrations to the wiring substrate, and a frequency of the ultrasonic vibrations is 20 to 70 kHz.

12. The desmearing method according to claim 2, wherein said wetting step and said wet-type ultraviolet beam irradiating step are repeatedly performed prior to said physical vibration applying step.

13. The desmearing method according to claim 2 further comprising a step of removing unnecessary water from the treatment target portion between said wetting step and said wet-type ultraviolet beam irradiating step.

14. The desmearing apparatus according to claim 4, wherein the treatment target portion includes at least one of a first smear derived from an organic substance and a second smear derived from an inorganic smear.

15. The desmearing apparatus according to claim 4, wherein the wet-type ultraviolet beam irradiating unit has a plurality of ultraviolet lamps, and each of the ultraviolet lamps emits the ultraviolet beam at a wavelength equal to or shorter than 220 nm.

16. The desmearing apparatus according to claim 4, wherein the physical vibration applying unit has a water tank that reserves water, and an ultrasonic oscillator that applies the physical vibrations to the wiring substrate material while the wiring substrate material being immersed in the water of the water tank.

17. The desmearing apparatus according to claim 4, wherein said at least one wet-type ultraviolet beam irradiating unit has a plurality of wet-type ultraviolet beam irradiating units arranged in parallel to each other.

18. The desmearing apparatus according to claim 4 further comprising an oxygen source to supply oxygen into the gas atmosphere.

19. The desmearing apparatus according to claim 4 further comprising an air knife for removing unnecessary water from the treatment target portion before the wet-type ultraviolet beam irradiating unit irradiates the treatment target portion with the ultraviolet beam.
